(19) United States
(12) Patent Application Publication
(10) Pub. No.: US 2022/0352120 A1
(43) Pub. Date: Nov. 3, 2022

(54) INTERPOSER AND ELECTRONIC DEVICE INCLUDING INTERPOSER

(71) Applicant: Samsung Electronics Co., Ltd., Gyeonggi-do (KR)

(72) Inventors: Eunseok HONG, Gyeonggi-do (KR); Sanghoon PARK, Gyeonggi-do (KR); Younoh CHI, Gyeonggi-do (KR)

(21) Appl. No.: 17/860,531

(22) Filed: Jul. 8, 2022

Related U.S. Application Data
(63) Continuation of application No. PCT/KR2021/008521, filed on Jul. 5, 2021.

(30) Foreign Application Priority Data
Jul. 3, 2020 (KR) 10-2020-0081867

(51) Int. Cl. H01L 25/065; H01L 23/538; H05K 3/46; H05K 1/02; H05K 1/14

(52) U.S. Cl. CPC H01L 25/0652; H01L 23/5385; H05K 3/4673; H05K 1/0292; H05K 1/142

(57) ABSTRACT

An interposer array is provided, which includes an array substrate, a first interposer configured as a closed curve having a first space therein, a second interposer configured as a closed curve having a second space therein, a plurality of first bridges configured to connect the array substrate and the first interposer, and a plurality of second bridges configured to connect the first interposer and the second interposer.

### CROSS-REFERENCE TO RELATED APPLICATION(S)

This application is a National Phase Entry of International Application No. PCT/KR2021/008521, which was filed on Jul. 5, 2021, and claims priority to Korean Patent Application No. 10-2020-0081867, filed in the Korean Intellectual Property Office on Jul. 3, 2020, the entire content of each of which is incorporated herein by reference.

### BACKGROUND

### 1. Field

The disclosure relates generally to an interposer and an electronic device including an interposer.

### 2. Description of Related Art

Electronic devices (e.g., mobile electronic devices) are becoming thinner, lighter, more compact, and multifunctional. An electronic device often includes a printed circuit board (PCB) (e.g., a printed board assembly (PBA), a rigid-flexible PCB (RFPCB), a flexible PCB (FPCB), etc.) on which various components are mounted. The PCB may include a processor, a memory, a sensor module, a camera module, a communication module, an input module, and an output module of the electronic device. The PCB may include a circuit wire for connecting multiple electronic components mounted thereon. It is also possible to stack multiple PCBs vertically and arrange different types of interposers between the multiple PCBs, such that the multiple PCBs are electrically connected, thereby implementing a composite PCB.

For example, an interposer having a via and a component-mounting space formed therein may be disposed between a first PCB and a second PCB. The first PCB and the second PCB may be vertically stacked in order to provide a package substrate including an interposer that is capable of securing a space for mounting a component and/or a battery inside an electronic device.

Different types of interposers may be disposed between multiple PCBs. However, if the different types of interposers have different heights, a separate process for accommodating the thickness dispersion of the electronic device is necessary.

In addition, manufacturing different types of interposers through respective manufacturing methods increases the interpose manufacturing cost.

### SUMMARY

The disclosure is provided to address at least the above-mentioned problems and/or disadvantages and to provide at least the advantages described below.

An aspect of the disclosure is to provide a method for manufacturing different types of interposers through a single process, thereby reducing the interpose manufacturing cost.

Another aspect of the disclosure is to provide a method for manufacturing different types of interposers that have substantially the same thickness, thereby improving the thickness dispersion of the electronic device including the different types of interposers.

Another aspect of the disclosure is to provide an interposer manufacturing method capable of manufacturing an interposer array including different types of interposers through a single manufacturing method.

In accordance with an aspect of the disclosure, an interposer array is provided, which includes an array substrate; a first interposer configured as a first closed curve having a first space therein; a second interposer configured as a second closed curve having a second space therein; a first bridge configured to connect the array substrate and the first interposer; and a second bridge configured to connect the first interposer and the second interposer.

In accordance with another aspect of the disclosure, an interposer is provided, which includes a first interposer configured as a closed curve having a first space therein, wherein the first interposer is disposed between a first PCB and a second PCB that are vertically stacked, and a first plating layer formed on a first side surface outside the first space.

In accordance with another aspect of the disclosure, an electronic device is provided, which includes a first package substrate and a second package substrate. The first package substrate includes a first PCB, a second PCB vertically stacked on the first PCB, and a first interposer disposed between the first PCB and the second PCB. The second package substrate includes a third PCB, a fourth PCB vertically stacked on the third PCB, and a second interposer disposed between the third PCB and the fourth PCB. The first interposer is configured as a first closed curve having a first space therein. The second interposer is configured as a second closed curve having a second space therein. The second interposer is smaller in size than the first space of the first interposer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates an electronic device in a network environment according to an embodiment;

FIG. 2 illustrates a front view of an electronic device according to an embodiment;

FIG. 3 illustrates a rear view of an electronic device according to an embodiment;

FIG. 4 illustrates an exploded view of an electronic device according to an embodiment;

FIG. 5A illustrates a package substrate including two interposers according to an embodiment;

FIG. 5B illustrates package substrates, each including an interposer, according to an embodiment;

FIG. 5C illustrates a package substrate including two interposers according to an embodiment;

FIG. 6A illustrates a first interposer according to an embodiment;

FIG. 6B illustrates a second interposer according to an embodiment;

FIG. 6C illustrates a method of manufacturing a first interposer 620 and a second interposer 640 according to an embodiment;

FIG. 6D illustrates a cross-sectional view of the first interposer and the second interposer taken along line I-I′ of FIG. 6C, according to an embodiment;

FIG. 7A illustrates an interposer array (e.g., an interposer panel) including a plurality of interposer units in which one interposer unit includes a first interposer and a second interposer, according to an embodiment;

FIG. 7B illustrates a second interposer and a unit dummy connected through a third bridge, according to an embodiment;

FIG. 8 illustrates a first bridge formed between an array substrate and a first interposer, and a second bridge formed between the first interposer and a second interposer, according to an embodiment;

FIG. 9 illustrates a first bridge formed between an array substrate and a first interposer, and a second bridge formed between the first interposer and a second interposer, according to an embodiment;

FIG. 10A illustrates a plating layer formed on the surface of a first side (e.g., outer side) of a first interposer and a plating layer not formed on a portion with a bridge removed, according to an embodiment;

FIG. 10B illustrates a plating layer formed on the surface of a second side (e.g., inner side) of a first interposer and a plating layer not formed on a portion with a bridge removed, according to an embodiment;

FIG. 11A illustrates a plating layer formed on the surface of a first side (e.g., outer side) of a second interposer and a plating layer not formed on a portion with a bridge removed, according to an embodiment;

FIG. 11B illustrates a plating layer formed on the surface of a second side (e.g., inner side) of a second interposer, according to an embodiment;

FIG. 11C illustrates a plating layer formed on the surface of a second side (e.g., inner side) of a second interposer, according to an embodiment;

FIG. 12A illustrates a shield layer formed inside a first side surface (e.g., outer side surface) of a first interposer, according to an embodiment;

FIG. 12B illustrates a shield layer formed inside a first side surface (e.g., outer side surface) of a first interposer, according to an embodiment;

FIG. 13A illustrates a shield layer formed inside a second side surface (e.g., inner side surface) of a first interposer, according to an embodiment;

FIG. 13B illustrates a shield layer formed inside a second side surface (e.g., inner side surface) of a first interposer, according to an embodiment;

FIG. 14A illustrates a shield layer formed inside a first side surface (e.g., outer side surface) of a second interposer, according to an embodiment;

FIG. 14B illustrates a shield layer formed inside a first side surface (e.g., outer side surface) of a second interposer, according to an embodiment;

FIG. 15A illustrates a shield layer formed inside a second side surface (e.g., inner side surface) of a second interposer, according to an embodiment; and

FIG. 15B illustrates a shield layer formed inside a second side surface (e.g., inner side surface) of a second interposer, according to an embodiment.

### DETAILED DESCRIPTION

Hereafter, various embodiments are described with reference to the accompanying drawings. For the convenience of description, the sizes of the components shown in the figures may be exaggerated or reduced and the disclosure is not necessarily limited to those shown in the figures. Additionally, descriptions of well-known functions and constructions are omitted for the sake of clarity and conciseness.

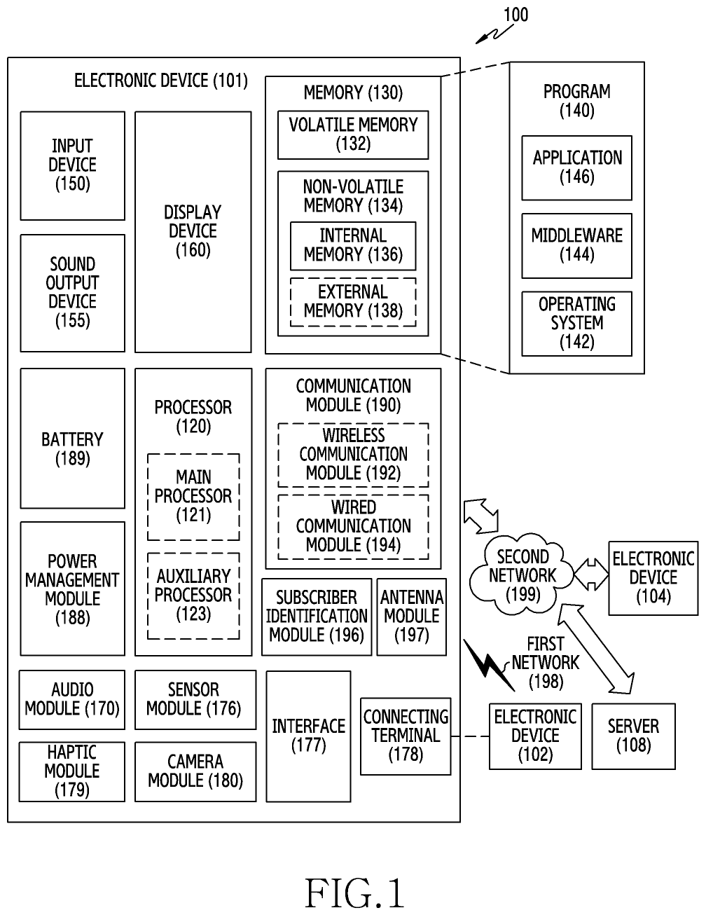

FIG. 1 illustrates an electronic device in a network environment according to an embodiment.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an ISP or a CP) may be implemented as part of another component (e.g., the camera module 180 or the communication module 190) functionally related to the auxiliary processor 123. According to an embodiment, the auxiliary processor 123 (e.g., the NPU) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent DNN (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, ISPs, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., the AP) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or IR data association (IrDA)) or the second network 199 (e.g., a long-range communication network, such as a legacy cellular network, a 5^{th} generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network, after a 4^{th} generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a PCB). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a PCB, an RFIC disposed on a first surface (e.g., the bottom surface) of the PCB, or adjacent to the first surface and capable of supporting a designated high-frequency band (e.g., the mmWave band), and a plurality of antennas (e.g., array antennas) disposed on a second surface (e.g., the top or a side surface) of the PCB, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or MEC. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

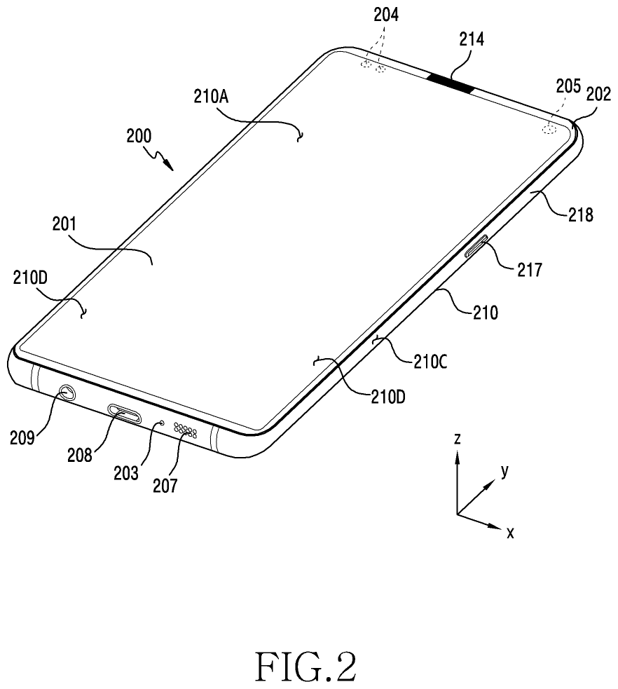

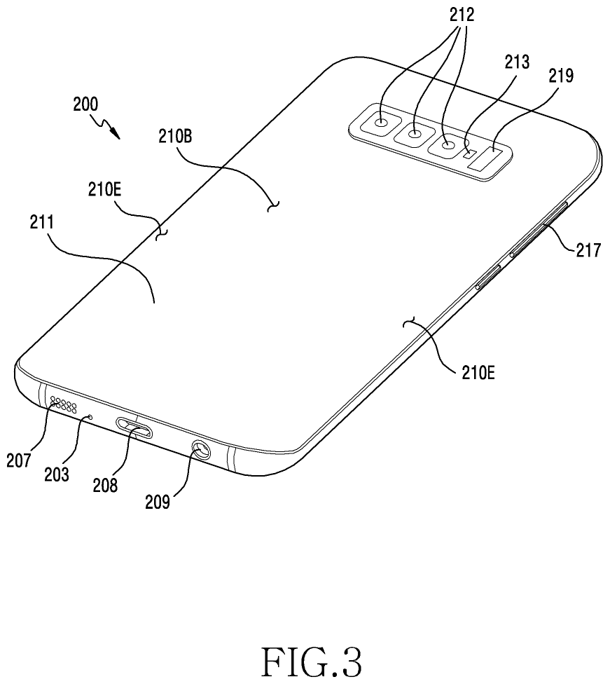

FIG. 2 illustrates a front view of an electronic device according to an embodiment. FIG. 3 illustrates a rear view of an electronic device according to an embodiment.

Referring to FIGS. 2 and 3, an electronic device 200 includes a housing 210 having a first surface (or a front surface) 210A, a second surface (or a rear surface) 210B, and a side surface 210C surrounding the space between the first surface 210A and the second surface 210B. Alternatively, the housing may imply a structure including some of the first surface 210A, the second surface 210B, and the side surface 210C.

The first surface 210A may be configured by a front plate 202 (e.g., a glass plate or a polymer plate including various coating layers), at least a part of which is substantially transparent. The second surface 210B may be configured by an opaque rear plate 211, at least a part of which is substantially opaque. The rear plate 211 may be made of coated or colored glass, ceramic, a polymer, metal (e.g., aluminum, stainless steel (STS), or magnesium), or a combination of at least two of these materials. The side surface 210C is coupled to a front plate 202 and a rear plate 211 and may be formed by a lateral bezel structure 218 (or a “lateral member”) including metal and/or a polymer. The rear plate 211 and the lateral bezel structure 218 may be integrated and may include the same material (e.g., a metallic material, such as aluminum).

The front plate 202 may have two first regions 210D, which bend toward the rear plate 211 from the first surface 210A and seamlessly extend, at both long edges of the front plate 202. The rear plate 211 may have two second regions 210E, which bend toward the front plate 202 from the second surface 210B and seamlessly extend, at both long edges. The front plate 202 (or the rear plate 211) may include only one of the first regions 210D (or the second regions 210E). Some of the first regions 210D or the second regions 210E may be omitted. When viewed from a side surface of the electronic device 200, the lateral bezel structure 218 may have a first thickness (or width) at the side surfaces not including the first regions 210D or the second regions 210E and may have a second thickness smaller than the first thickness at the side surfaces including the first regions 210D or the second regions 210E.

The electronic device 200 includes at least one of a display 201, an input device 203, sound input/output (I/O) devices 207 and 214, sensor modules 204 and 209, camera modules 205, 212, and 213, a key input device 217, an indicator, and connector holes 208 and 209. Alternatively, the electronic device 200 may not include at least one (e.g., the key input devices 217) of the components illustrated in FIGS. 2 and 3 or may further include other components.

The display 201 may be seen through the upper end portion of the front plate 202. At least a portion of the display 201 may be seen through the first surface 210A and the front plate 202 forming the first regions 210D of the side surface 210C. The display 201 may be coupled to or disposed adjacent to a touch sensing circuit, a pressure sensor that can measure the intensity (pressure) of a touch, and/or a digitizer that detects a magnetic stylus pen. At least some of the sensor modules 204 and 219 and/or at least some of the key input devices 217 may be disposed in the first regions 210D and/or the second regions 210E.

At least one or more of the audio module 214, the sensor module 204, the camera module 205 (e.g., an image sensor), and the fingerprint sensor may be disposed on the rear surface of the display region of the display 201. The display 201 may be coupled to or disposed adjacent to a touch sensing circuit, a pressure sensor that can measure the intensity (pressure) of a touch, and/or a digitizer that detects a magnetic stylus pen. At least some of the sensor modules 204 and 219 and/or at least some of the key input devices 217 may be disposed in the first regions 210D and/or the second regions 210E.

The input device 203 may include a microphone. The input device 203 may include a plurality of microphones disposed to be able to sense the direction of sound. The sound output devices 207 and 214 may include speakers 207 and 214. The speakers 207 and 214 may include an external speaker 207 and a receiver for a telephone call (e.g., the audio module 214). The input device 203 (e.g., a microphone), the speakers 207 and 214, and the connector holes 208 and 209 may be disposed in the space of the electronic device 200 and may be exposed to the external environment through at least one hole formed at the housing 210. The hole formed through the housing 210 may be used in common for the input device 203 (e.g., a microphone) and the speakers 207 and 214. The speakers 207 and 214 may include a speaker (e.g., a piezo speaker) operating without the hole formed through the housing 210.

The sensor modules 204 and 219 can generate an electrical signal or a data value corresponding to the internal operation state of the electronic device 200 or an external environmental state. The sensor modules 204 and 219 may include a first sensor module 204 (e.g., a proximity sensor) and/or a second sensor module (e.g., a fingerprint sensor) disposed on the first surface 210A of the housing 210, and/or a third sensor module 219 (e.g., a heart rate monitor (HRM) sensor) disposed on the second surface 210B of the housing 210. The fingerprint sensor may be disposed on the first surface 210A (e.g., the display 201) and/or the second surface 210B of the housing 210. The electronic device 200 may further include a sensor module including at least one of a gesture sensor, a gyro sensor, a barometer sensor, a magnetic sensor, an acceleration sensor, a grip sensor, a color sensor, an IR sensor, a biosensor, a temperature sensor, a humidity sensor, or an illumination sensor.

The camera modules 205 and 212 may include a first camera module 205 disposed on the first surface 210A of the electronic device 200, and a second camera module 212 and/or a flash 213 disposed on the second surface 210B. The camera modules 205 and 212 may include one or more lenses, an image sensor, and/or an ISP. A flash 213 may include a light emitting diode (LED) or a xenon lamp. The first camera module 205 may be disposed at the lower portion of the display panel in an under display camera (UDC) type. Two or more lenses (e.g., a wide-angle lens and a telephoto lens) and image sensors may be disposed on one surface of the electronic device 200. A plurality of first camera modules 205 may be disposed in a UDC type on the first surface (e.g., the surface on which an image is displayed) of the electronic device 200.

The key input device 217 may be disposed on the side surface 210C of the housing 210. Alternatively, the electronic device 200 may omit some or all of the key input devices 217 described above and the non-included key input devices 217 may be implemented in other types such as software keys on the display 201. The key input devices 217 may be implemented using the pressure sensor included in the display 201.

The indicator may be disposed on the first surface 210A of the housing 210. The indicator may provide state information of the electronic device 200 in a light type. The indicator may provide a light source linked to the operation of the camera module 205. The indicator may include an LED, an IR LED, and/or a xenon lamp.

The connector holes 208 and 209 may include a first connector hole 208 that can accommodate a connector (e.g., a USB connector) for transmitting and receiving power and/or data to and from external electronic devices and/or a second connector hole 209 (or an earphone jack) that can accommodate a connector for transmitting and receiving audio signals to and from external electronic devices.

Some camera module 205 of camera modules 205 and 212, some sensor module 204 of sensor modules 204 and 219, or the indicator may be disposed to be seen through the display 201. The camera module 205 may be disposed to overlap the display region and an image may be displayed also in the display region corresponding to the camera module 205. Some sensor module 204 may be disposed in the internal space of the electronic device to perform its function without being visually exposed through the front plate 202.

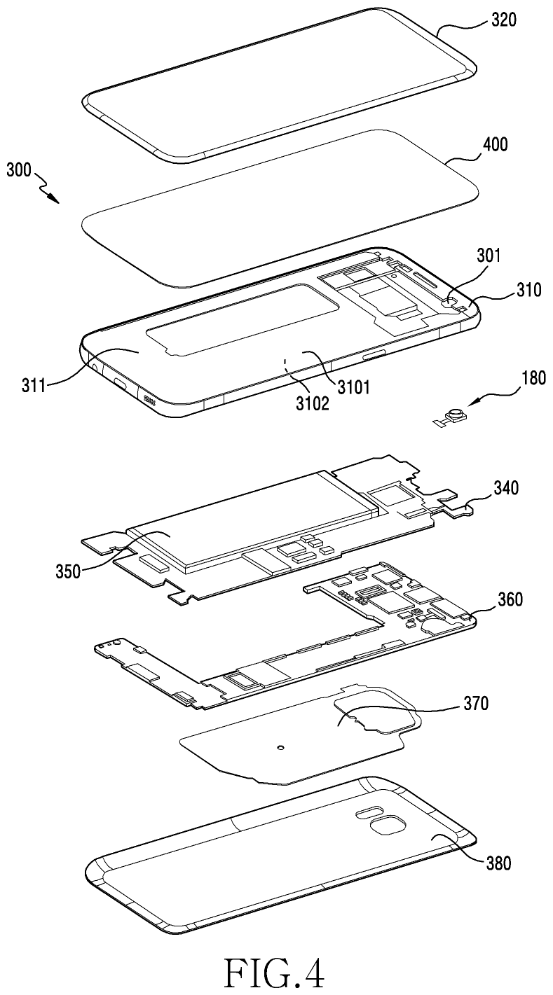

FIG. 4 illustrates an exploded view of an electronic device according to an embodiment.

Referring to FIG. 4, an electronic device 300 includes a lateral member 310 (e.g., a lateral bezel structure), a first supporting member 311 (e.g., a bracket or a supporting structure), a front plate 320 (e.g., a front cover), a display 400, a PCB 340, a battery 350, a second supporting member 360 (e.g., a rear case), an antenna 370, and a rear plate 380 (e.g., a rear cover).

The electronic device 300 may not include at least one (e.g., the first supporting member 311 or the second supporting member 360) of the components, or may further include other components. At least one of the components of the electronic device 300 may be the same as or similar to at least one of the components of the electronic device 101 of FIG. 1 or the electronic device 200 of FIG. 3 and repeated description is omitted below.

The first supporting member 311 is disposed in the electronic device 300 and may be connected with the lateral member 310 or may be integrally formed with the lateral member 310. The first supporting member 311 may be made of a metallic material and/or a non-metallic material (e.g., a polymer). The display 330 may be coupled to one surface of the first supporting member 311, while the PCB 340 is coupled to the other surface thereof. A processor, a memory, and/or an interface may be mounted on the PCB 340. The processor may include one or more of a CPU, an AP, a graphic processor, an ISP, a sensor hub processor, or a CP.

The PCB 340 may include a plurality of PCBs (e.g., a first PCB and a second PCB) and at least one interposer. The plurality of PCBs may include a package substrate. The plurality of PCBs may be PCBs made of a material (e.g., FR4) having a non-bendable characteristic or FPCBs having a bendable characteristic (or a flexible characteristic).

The PCB 340 may include an area (e.g., a flexible area) having a bendable or flexible characteristic (e.g., an FPCB or an RFPCB). The flexible area may include a base film (or substrate) and a copper clad layer. The flexible area may be a flexible copper clad layer (FCCL) formed by stacking at least one copper clad in at least a portion of at least one region of the upper end or the lower end of a polyimide film.

The memory may include a volatile memory or a nonvolatile memory.

The interface may include an HDMI, a USB interface, an SD card interface, and/or an audio interface. The interface can electrically or physically connect the electronic device 300 to external electronic devices and may include an USB connector, an SD card/multimedia card (MMC) connector, or an audio connector.

The battery 350 supplies power to one or more components of the electronic device 300, and may include a primary battery that is not rechargeable, a secondary battery that is rechargeable, and/or a fuel cell. At least a portion of the battery 350 may be disposed in substantially the same plane as the PCB 340. The battery 350 may be integrally disposed in the electronic device 300. The battery 350 may be disposed to be detachable from the electronic device 300.

The antenna 370 may be disposed between the rear plate 380 and the battery 350. The antenna 370 may include a near field communication (NFC) antenna, a wireless charging antenna, and/or a magnetic secure transmission (MST) antenna. The antenna 370 can perform NFC with external devices or can wirelessly transmit and receive power for charging. The antenna structure may be formed by a portion or a combination of the lateral member 310 and/or the first supporting member 311.

A shield layer (or a shield can) may be made of a conductive material (e.g., metal), and may be disposed in at least one region of the PCB 340, in order to electromagnetically shield the plurality of electronic parts (e.g., a processor, a memory, an interface, a communication module, a sensor module, and/or a connection terminal) disposed on the PCB 340. The shield structure may be disposed at least partially on the first PCB and/or the second PCB, and can electromagnetically shield the plurality of electronic parts disposed on the first PCB and/or the second PCB.

The first supporting member 311 of the lateral member 310 may include a first surface 3101 facing the front plate 320 and a second surface 3102 facing the opposite direction of the first surface 3101 (e.g., the rear plate direction).

The camera module 180 may be disposed between the first supporting member 311 and the rear plate 380. The camera module 180 may be disposed to be seen or to protrude toward the front plate 320 through a through-hole 301 connected from the first surface 3101 to the second surface 3102 of the first supporting member 311. The portion of the camera module 180 protruding through the through-hole 301 may be disposed at a corresponding position of the display 400 to detect an external environment. When the camera module 180 is disposed between the display 400 and the first supporting member 311, the through-hole 301 may not be needed.

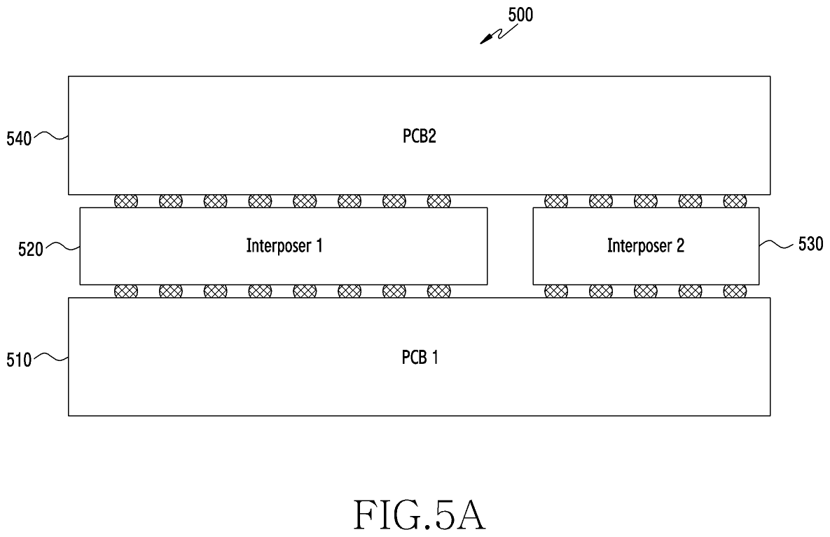

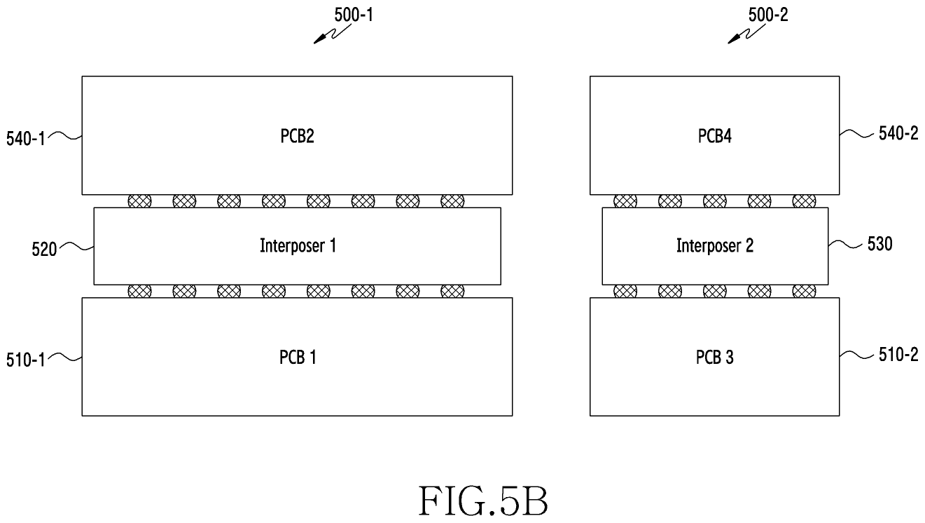

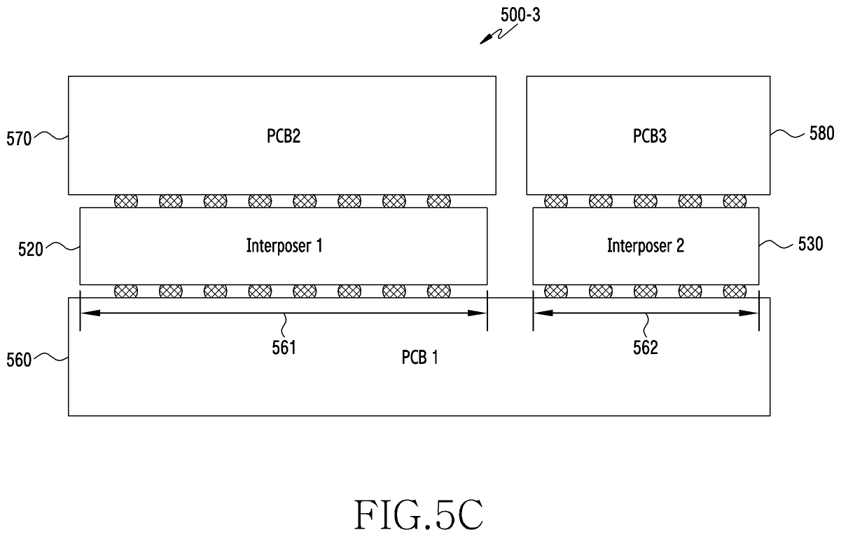

FIG. 5A illustrates a package substrate including two interposers according to an embodiment.

Referring to FIG. 5A, an electronic device may include a package substrate 500. The package substrate 500 includes a first PCB 510 (e.g., a main PCB), a second PCB 540 (e.g., a slave PCB), and two interposers (e.g., the first interposer 520 and the second interposer 530) that are vertically stacked. Different types of interposers may be disposed between the first PCB 510 and the second PCB 540.

Although FIG. 5A illustrates an example including the first interposer 520 and the second interposer 530, which are different types and are disposed between the first PCB 510 and the second PCB 540, the disclosure is not limited thereto.

FIG. 5B illustrates two package substrates, each including an interposer, according to an embodiment.

Referring to FIG. 5B, an electronic device may include a plurality of package substrates (e.g., the package substrates 500-1 and 500-2). An interposer may be disposed on each of the plurality of package substrates 500-1 and 500-2. A different type of interposer may be disposed on the plurality of package substrates 500-1 and 500-2.

More specifically, the first package substrate 500-1 includes a first PCB 510-1, a second PCB 540-1, and a first interposer 520. The first interposer 520 is disposed between the first PCB 510-1 and the second PCB 540-1. The second package substrate 500-2 includes a third PCB 510-2, a fourth PCB 540-2, and a second interposer 530. The second interposer 530 is disposed between the third PCB 510-2 and the fourth PCB 540-2. The first interposer 520 and the second interposer 530 may be formed in different sizes and/or shapes.

FIG. 5C illustrates a package substrate including two interposers according to an embodiment.

Referring to FIG. 5C, an electronic device may include the package substrate 500-3. The package substrate 500-3 includes a first PCB 560 (e.g., a main PCB), a second PCB 570 (e.g., a slave PCB), a third PCB 580 (e.g., another slave PCB), and two interposers (e.g., the first interposer 520 and the second interposer 530). The second PCB 570 is stacked to overlap a first part 561 of the first PCB 560. The third PCB 580 is stacked to overlap a second part 662 different (spaced) from the first part 561 of the first PCB 560. The first interposer 520 is disposed between the first PCB 560 and the second PCB 570. The second interposer 530 is disposed between the first PCB 560 and the third PCB 580. The first interposer 520 and the second interposer 530 may be formed in different sizes and/or shapes.

In FIGS. 5A to 5C, the first PCB 510, 510-1, 510-2, or 560 may include a processor (e.g., an AP and/or a CP), a memory, and a power management circuit.

The second PCB 540, 540-1, 540-2, or 570 and/or the third PCB 580 may include a radio frequency (RF) circuit, an NFC chip, a ultra-wide band (UWB) chip, a sensor circuit, a transceiver, a wireless communication module (e.g., a Wi-Fi module), and a connector module for connection with an external electronic device. The connector module may include a USB C-type connector, a display connector, and/or a battery connector.

The first interposer 520 and/or the second interposer 530 may include a power interface, a USB interface, an MIPI interface, an RF interface, through-electrodes, wires, and a ground (GND) terminal. The first PCB 510, 510-1, or 510-2 and the second PCB 540, 540-1, or 540-2 can be electrically connected by the first interposer 520 and/or the second interposer 530. The first PCB 510, 510-1, or 510-2 can transmit a digital signal related to an RF band to the second PCB 540, 540-1, or 540-2 through the first interposer 520 and/or the second interposer 530.

The first interposer 520 and/or the second interposer 530 may have a copper clad laminate (CCL) structure including a plurality of preimpregnated (PREPREG) (PPG) material layers (e.g., an insulating resin layers) and a copper clad disposed therebetween.

Plating layers of the first interposer 520 and the second interposer 530 may be electrically connected with the ground terminal of the first interposer 520 and the second interposer 530 in order to remove or reduce electromagnetic interference (EMI) among parts disposed inside and outside. The ground of the first PCB 510 and the ground of the second PCB 540 can be electrically connected by the first interposer 520 and/or the second interposer 530.

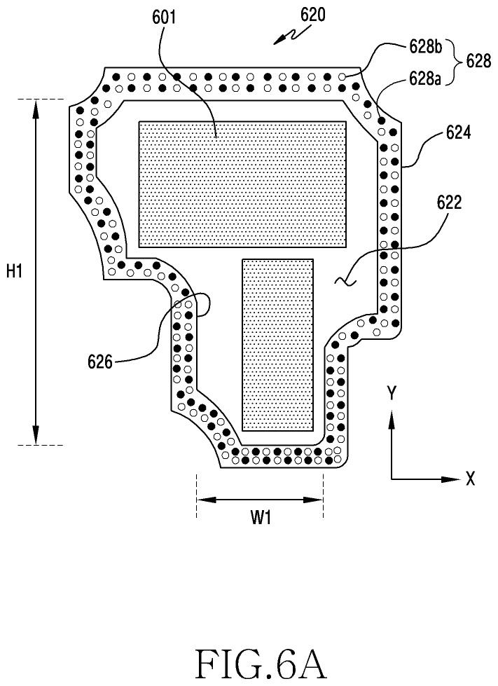

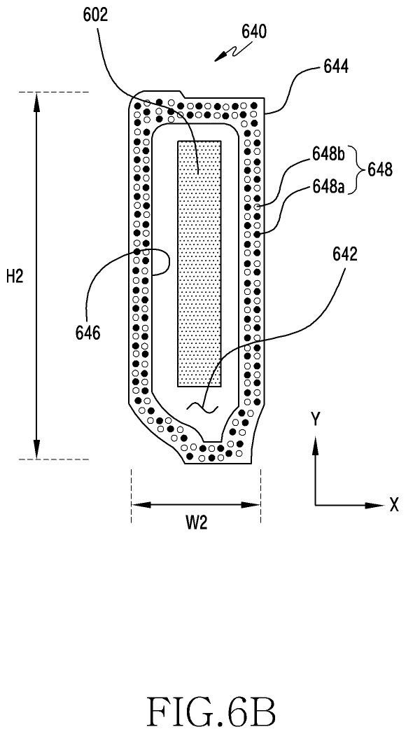

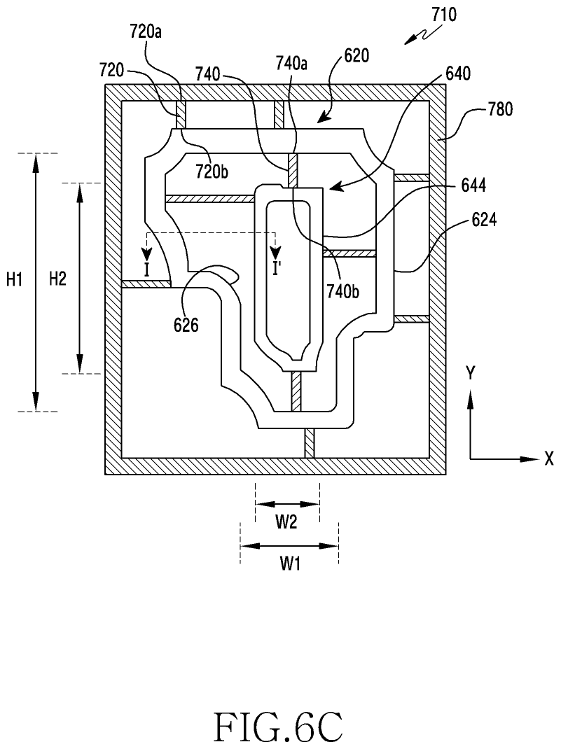

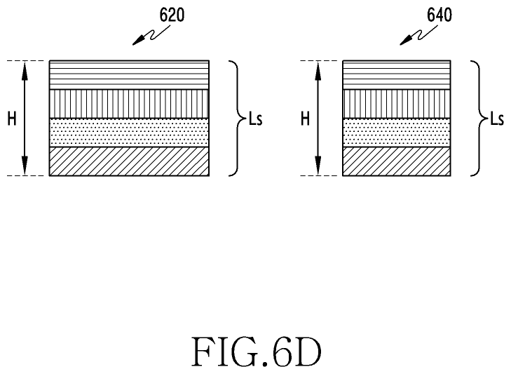

FIG. 6A illustrates a first interposer according to an embodiment.

Referring to FIG. 6A, the first interposer 620 may be formed in a closed curve shape having a space 622 therein. At least one part 601 may be disposed in the internal space 622 of the first interposer 620. The at least one part 601 may be electrically connected with the first PCB. The first interposer 620 may include a plurality of vias 628 for electrically connecting the first PCB and the second PCB. The plurality of vias 628 may include a plurality of signal vias 628a for transmitting signals and a plurality of ground vias 628b for grounding.

FIG. 6B illustrates a second interposer according to an embodiment.

Referring to FIG. 6B, the second interposer 640 may be formed in a closed curve shape having a space 642 therein. At least one part 602 may be disposed in the internal space 642 of the second interposer 640. The at least one part 602 may be electrically connected with the first PCB. The second interposer 640 may include a plurality of vias 648 for electrically connecting the first PCB and the second PCB.

The plurality of vias 648 may include a plurality of signal vias 648a for transmitting signals and a plurality of ground vias 648b for grounding. A solder bump or a solder ball may be formed on the upper surface and/or the lower surface of the first interposer 620 and the second interposer 640, and a plurality of rewiring layer may be included therein.

Referring to FIGS. 6A and 6B, the first interposer 620 and the second interposer 640 may be configured as silicon substrates. Not limited thereto, the first interposer 620 and the second interposer 640 may be made of the same material as the first PCB and the second PCB.

The length H1 of the inner diameter in a first direction (e.g., Y-axial direction) of the first interposer 620 may be larger than the length H2 of the outer diameter in the first direction (e.g., Y-axial direction) of the second interposer 640. The length W1 of the inner diameter in a second direction (e.g., X-axial direction) of the first interposer 620 may be larger than the length W2 of the outer diameter in the second direction (e.g., X-axial direction) of the second interposer 640.

The second interposer 640 may be formed in a size smaller than the space 622 of the first interposer 620. The outer diameter of the second interposer may be smaller by about 0.5 mm to about 5 mm than the inner diameter of the first interposer 620.

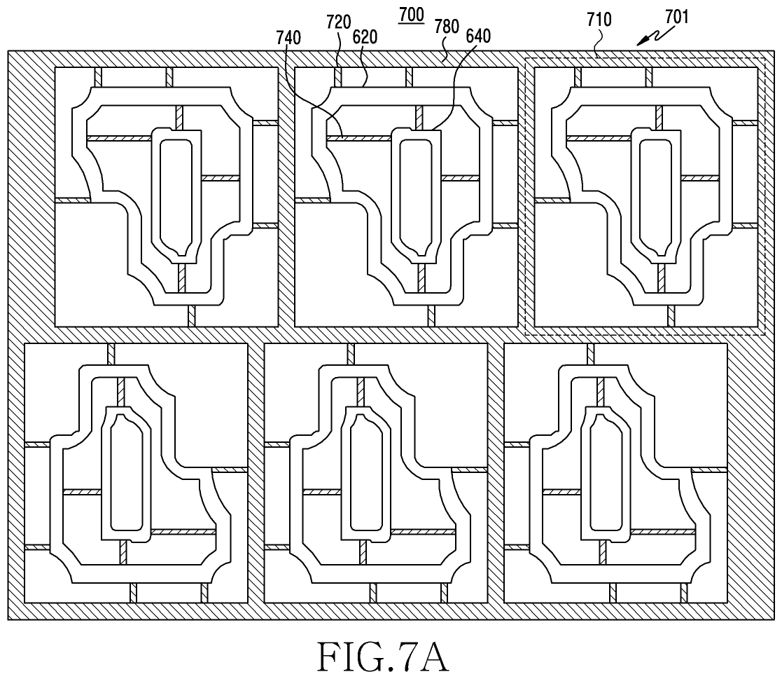

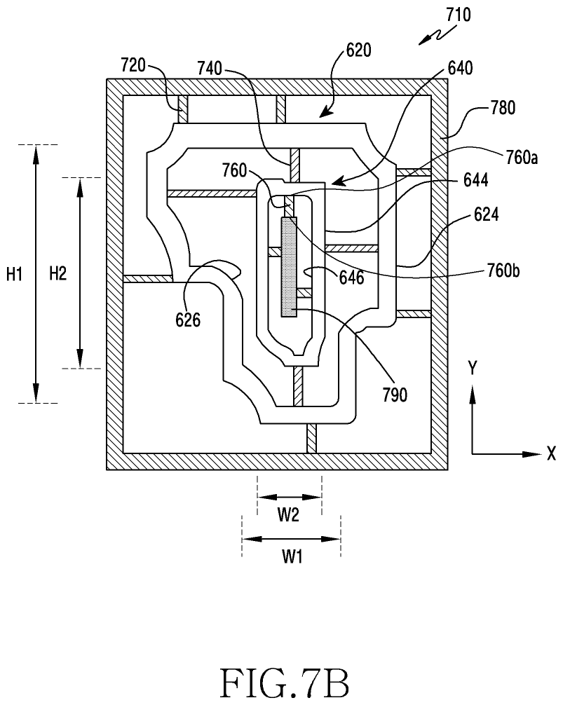

FIG. 6C illustrates a method of manufacturing a first interposer and a second interposer according to an embodiment. FIG. 6D illustrates a cross-sectional view of the first interposer 620 and the second interposer 640 taken along line I-I′ of FIG. 6C. FIG. 7A illustrates an interposer array (e.g., an interposer panel) including a plurality of interposer units in which one interposer unit includes a first interposer and a second interposer, according to an embodiment.

Referring to FIGS. 6C, 6D, and 7A, a state before a first bridge 720 and a second bridge 740 are removed in a manufacturing process of an interposer array 700 (e.g., interposer panel) including a first interposer 620 and a second interposer 640 is illustrated.

The interposer array 700 includes an array substrate 701, a plurality of interposer units 710, a plurality of first bridges 720, and a plurality of second bridges 740. A plurality of interposer arrays 710 may be disposed on one array substrate 701, and different types of first interposer 620 and second interposer 640 may be disposed in each of the plurality of interposer units 710. By manufacturing one array substrate 701, it is possible to manufacture different types of a plurality of first interposers 620 and also a plurality second interposers 640.

In order to fix the first interposer 620 in a manufacturing process of the array substrate 701, the first interposer 620 and a dummy 780 of the array substrate 701 may be connected by a plurality of first bridges 720. In order to fix the second interposer 640, the first interposer 620 and the second interposer 640 may be connected by a plurality of second bridges 740. When the first interposer 620 and the second interposer 640 are finished being manufactured, it is possible to remove the plurality of first bridges 720 and the plurality of second bridges 740 through a cutting process.

Although FIGS. 6C and 7A illustrate an example in which the array substrate 701 and the first interposer 620 are connected by six first bridges 720 in one interposer unit 710, the number of the first bridges 720 connecting the array substrate 701 and the first interposer 620 may be changed in accordance with the shape and/or size of the first interposer 620. Additionally, although FIGS. 6C and 7A illustrate an example in which the first interposer 620 and the second interposer 640 are connected by four second bridges 740 in one interposer unit 710, the number of the second bridges 740 connecting the first interposer 620 and the second interposer 640 may be changed in accordance with the shapes and/or sizes of the first interposer 620 and the second interposer 640.

Referring to FIG. 6D, the first interposer 620 and the second interposer 640 may include a plurality of layers Ls. The plurality of layers Ls are manufactured through the same process and may have substantially the same height. Accordingly, the entire height H of the plurality of layers Ls of the first interposer 620 and the entire height H of the plurality of layers Ls of the second interposer 640 are substantially the same, such that the first interposer 620 and the second interposer 640 may have substantially the same height H. A plurality of first wires formed in the first interposer 620 and a plurality of second wires formed in the second interposer 640 may be formed through the same process. A plurality of first vias formed in the first interposer 620 and a plurality of second vias formed in the second interposer 640 may be formed through the same process.

Although FIGS. 6C And 7A are directed to an example in which a specific bridge is not connected to a second side surface (e.g., inner side surface) of the second interposer 640, the disclosure is not limited thereto. Depending on the shape and/or size of the second interposer 640, a unit dummy (e.g., the unit dummy 790 of FIG. 7B) may be disposed in the internal space of the second interposer 640 (e.g., the space 642 of FIG. 6B) and the second interposer 640 and the unit dummy 790 may be connected by a plurality of third bridges (e.g., the third bridge 760 of FIG. 7B).

FIG. 7B illustrates a second interposer and a unit dummy connected by a third bridge according to an embodiment.

Referring to FIG. 7B, the interposer unit includes a first interposer 620, a second interposer 640, a plurality of first bridges 720, a plurality of second bridges 740, and a plurality of third bridges 760.

In order to fix the first interposer 620 in the manufacturing process of the array substrate, the first interposer 620 and a dummy 780 of the array substrate may be connected by a plurality of first bridges 720. In order to fix the second interposer 640, the first interposer 620 and the second interposer 640 may be connected by a plurality of second bridges 740. The second interposer 640 and the unit dummy 790 may be connected by the third bridges 760. When the first interposer 620 and the second interposer 640 are finished being manufactured, it is possible to remove the plurality of first bridges 720, the plurality of second bridges 740, and the plurality of third bridges 760 through a cutting process.

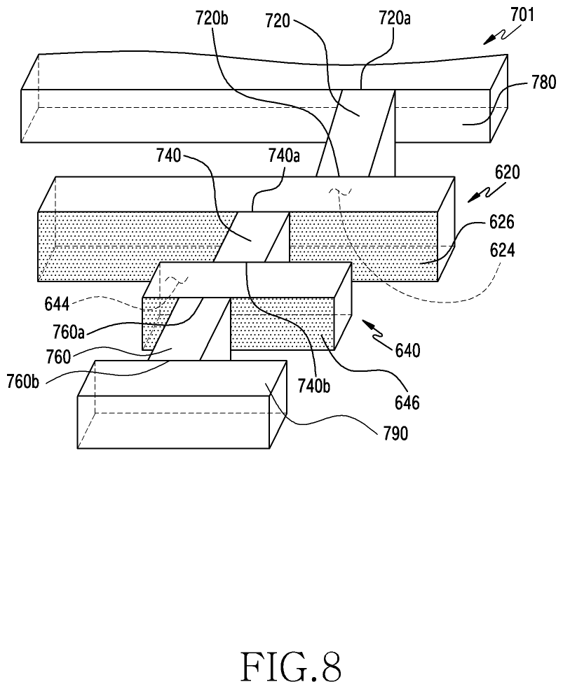

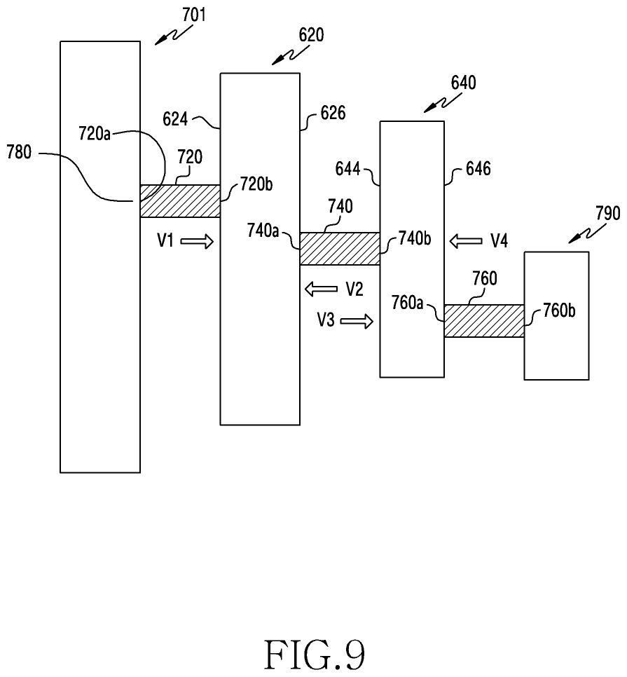

FIG. 8 illustrates a first bridge formed between an array substrate and a first interposer, and a second bridge formed between the first interposer and a second interposer, according to an embodiment. FIG. 9 illustrates a first bridge formed between an array substrate and a first interposer, and a second bridge formed between the first interposer and a second interposer, according to an embodiment.

More specifically, FIGS. 8 and 9 illustrate the first bridge 720 formed between the array substrate 701 and the first interposer 620, and the second bridge 740 formed between the first interposer 620 and the second interposer 640. Although FIGS. 8 and 9 illustrate one first bridge 720 and one second bridge 740 for simplicity, a plurality of first and second bridges may be utilized the same way.

Referring to FIGS. 7A, 8, and 9, a first side 720a of the first bridge 720 may be connected with the dummy 780 of the array substrate 701. A second side 720b of the first bridge 720 may be connected to the first side surface 624 (e.g., outer side surface) of the first interposer 620. A first side 740a of the second bridge 740 may be connected to the second side surface 626 (e.g., inner side surface) of the first interposer 620. A second side 740b of the second bridge 740 may be connected to the first side surface 644 (e.g., outer side surface) of the second interposer 640. When the first interposer 620 and the second interposer 640 are finished being manufactured, the plurality of first bridges 720 and the plurality of second bridges 740 can be removed by cutting. When the first bridges 720 and the second bridges 740 are removed by cutting, as illustrated in FIGS. 6A and 6B, the different types of first interposer 620 and the second interposer 640 are separated, thereby forming individual interposers 620 and 640.

Alternatively, as illustrated in FIG. 7B, the second interposer 640 and the unit dummy 790 may be connected by a plurality of third bridges 760. A first side 760a of the third bridge 760 may be connected to the second side surface 646 (e.g., inner side surface) of the second interposer 640. A second side 760b of the third bridge 760 may be connected to the unit dummy 790. When the first interposer 620 and the second interposer 640 finished being manufactured, it is possible to remove the plurality of first bridges 720, the plurality of second bridges 740, and the plurality of third bridges 760 by cutting. When the first bridges 720, the second bridges 740, and the third bridges 760 are removed by cutting, as illustrated in FIGS. 6A and 6B, the different types of first interposer 620 and the second interposer 640 are separated, forming individual interposers 620 and 640.

As described above, different types of a plurality first interposers 620 and a plurality of second interposers 640 may be simultaneously manufactured through the same process, whereby it is possible to reduce the manufacturing cost (e.g., by about ½) of the first interposer 620 and the second interposer 640. By simultaneously pre-soldering the different types of a plurality first interposers 620 and a plurality of second interposers 640, it is possible to reduce the production time and improve production yield. Pre-soldering may be achieved through a process (or a “reflow process”) of applying or squeezing a solder cream (e.g., “solder paste”) to protrusions of the first interposer 620 and/or the second interposer 640 using a metal mask and then melting the applied solder cream, but is not limited thereto.

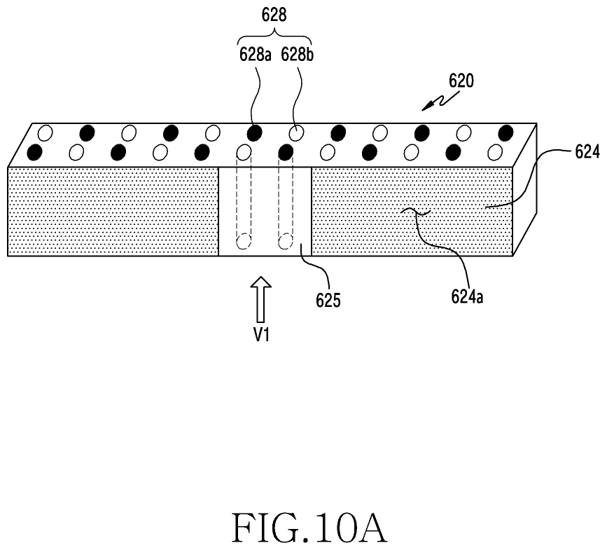

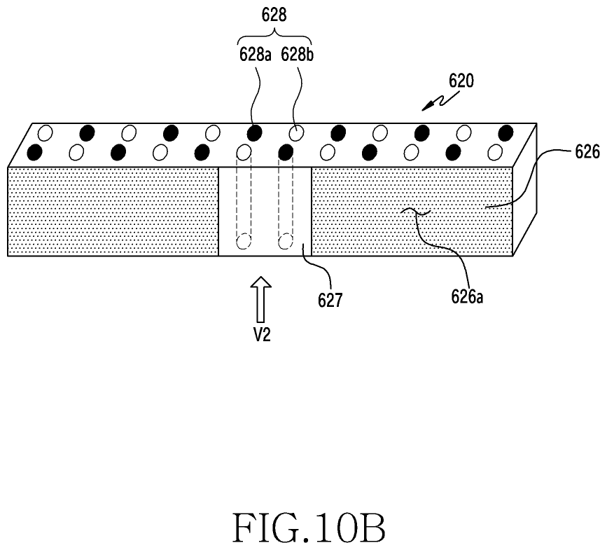

FIG. 10A illustrates a plating layer formed on the surface of a first side (e.g., outer side) of a first interposer and a plating layer not formed on a portion with a bridge removed, according to an embodiment. Specifically, FIG. 10A illustrates the first side surface 624 of the first interposer 620 seen in the first direction V1 in FIG. 9.

Referring to FIGS. 6A, 9, and 10A, in the manufacturing process, a first plating layer 624a (e.g., outer surface plating layer) may be formed on the first side surface 624 (e.g., outer side surface) of the first interposer 620. When the first plating layer 624a is formed on the first side surface 624 of the first interposer 620, the first bridge 720 (e.g., a plurality of first bridges 720) becomes a mask, so the first plating layer 624a is not formed at a first bridge connection portion 625.

When the first bridge 720 connecting the array substrate and the first interposer 620 is removed, the first plating layer 624a does not exist at the first bridge connection portion 625 where the first bridge 720 was connected of the first side surface 624 of the first interposer 620. The first plating layer 624a may be formed at other portions except for the first bridge connection portion 625 of the first side surface 624 of the first interposer 620. The first plating layer 624a may be electrically connected with at least one ground via 628b formed in the first interposer 620. The region corresponding to the first bridge connection portion 625, where the first plating layer 624a does not exist, may be shielded by a plurality of ground vias 628b.

As described above, the first plating layer 624a is formed on the first side surface 624 of the first interposer 620 and the region (e.g., the first bridge connection portion 625) where the first plating layer 624a is not formed may be shielded by the plurality of ground vias 628b. Accordingly, it is possible to remove or reduce EMI among parts disposed inside and/or outside the first interposer 620.

FIG. 10B illustrates a plating layer formed on the surface of a second side (e.g., inner side) of a first interposer and a plating layer not formed on a portion with a bridge removed, according to an embodiment. Specifically, FIG. 10B illustrates the second side surface 626 of the first interposer 620 seen in the second direction V2 of FIG. 9.

Referring to FIGS. 6A, 9, and 10B, in the manufacturing process, the second plating layer 626a (e.g., inner side surface plating layer) may be formed on the second side surface 626 (e.g., inner side surface) of the first interposer 620. When the second plating layer 626a is formed on the second side surface 626 of the first interposer 620, a second bridge 740 (or a plurality of second bridges 740) becomes a mask, so the second plating layer 626a is not formed at a second bridge connection portion 627.

When the second bridge 740 connecting the first interposer 620 and the second interposer 640 is removed, the second plating layer 626a does not exist at the second bridge connection portion 627 where the second bridge 740 was connected of the second side surface 626 of the first interposer 620. The second plating layer 626a may be formed at other portions except for the second bridge connection portion 627 of the second side surface 626 of the second interposer 620. The second plating layer 626a may be electrically connected with at least one ground via 628b formed in the first interposer 620. The region corresponding to the second bridge connection portion 627, where the second plating layer 626a does not exist, may be shielded by a plurality of ground vias 628b.

As described above, the second plating layer 626a is formed on the second side surface 626 of the first interposer 620 and the region (e.g., the second bridge connection portion 627) where the second plating layer 626a is not formed may be shielded by the plurality of ground vias 628b. Accordingly, it is possible to remove or reduce EMI among parts disposed inside and/or outside the first interposer 620.

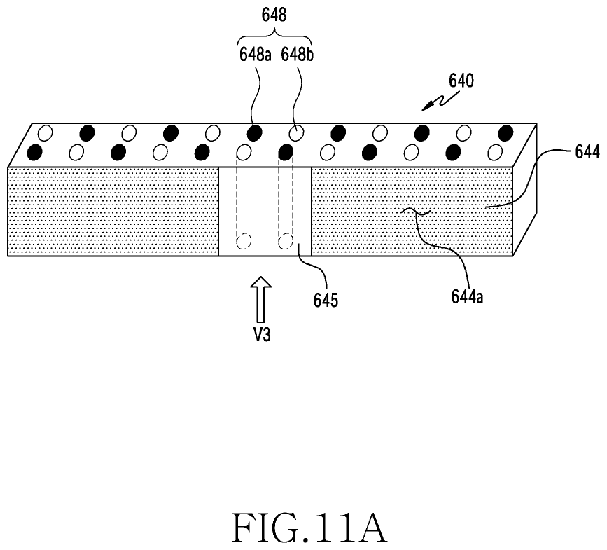

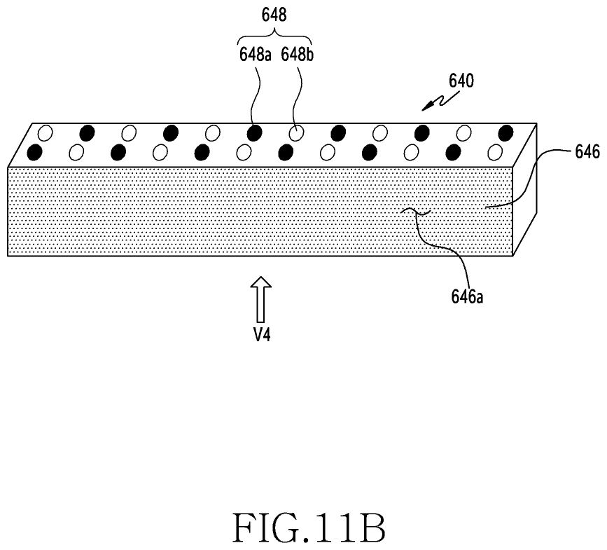

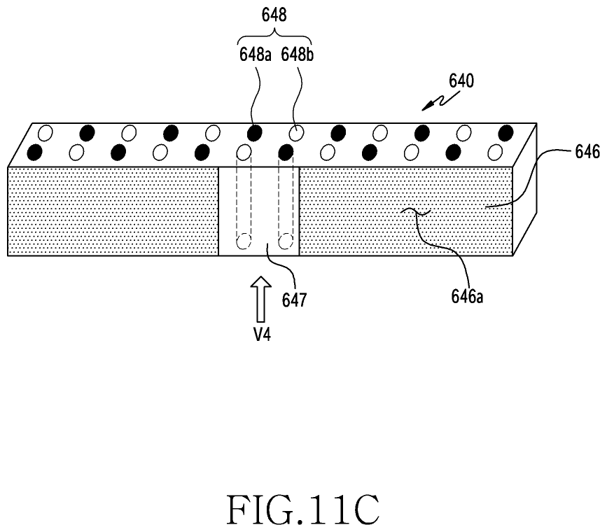

FIG. 11A illustrates a plating layer formed on the surface of a first side (e.g., outer side) of a second interposer and a plating layer not formed on a portion with a bridge removed, according to an embodiment. Specifically, FIG. 11A illustrates the first side surface 644 of the second interposer 640 seen in the third direction V3 of FIG. 9.

Referring to FIGS. 6A, 9, and 11A, in the manufacturing process, a third plating layer 644a (e.g., outer surface plating layer) may be formed on the first side surface 644 (e.g., outer side surface) of the second interposer 640. When the third plating layer 644a is formed on the first side surface 644 of the second interposer 640, a second bridge 740 (or a plurality of second bridges 740) becomes a mask, so the third plating layer 644a is not formed at a third bridge connection portion 645.

When the second bridge 740 connecting the first interposer 620 and the second interposer 640 is removed, the third plating layer 644a does not exist at the third bridge connection portion 645 where the second bridge 740 was connected of the first side surface 644 of the second interposer 640. The third plating layer 644a may be formed at other portions except for the third bridge connection portion 645 of the first side surface 644 of the second interposer 640. The third plating layer 644a may be electrically connected with at least one ground via 648b formed in the second interposer 640. The region corresponding to the third bridge connection portion 645, where the third plating layer 644a does not exist, may be shielded by a plurality of ground vias 648b.

As described above, the third plating layer 644a is formed on the first side surface 644 of the second interposer 640 and the region (e.g., the third bridge connection portion 645) where the third plating layer 644a is not formed may be shielded by the plurality of ground vias 628b. Accordingly, it is possible to remove or reduce EMI among parts disposed inside and/or outside the second interposer 640.

FIG. 11B illustrates a plating layer formed on the surface of a second side (e.g., inner side) of a second interposer, according to an embodiment. Specifically, FIG. 11B illustrates the second side surface 646 of the second interposer 640 as seen in the fourth direction V4 of FIG. 9.

Referring to FIGS. 6A, 9, and 11B, in the manufacturing process, the fourth plating layer 646a (e.g., outer surface plating layer) may be formed on the second side surface 646 (e.g., inner side surface) of the second interposer 640. The fourth plating layer 646a may be electrically connected with at least one ground via 648b formed in the second interposer 640.

As illustrated in FIG. 7A, when a specific unit dummy is not disposed in the internal space of the second interposer 640, the fourth plating layer 646a may be formed on the entire surface of the second side surface 646 of the second interposer 640. Since the fourth plating layer 646a is formed on the second side surface 646 of the second interposer 640, it is possible to remove or reduce EMI among parts disposed inside and/or outside the second interposer 640.

FIG. 11C illustrates a plating layer formed on the surface of a second side (e.g., inner side) of a second interposer, according to an embodiment.

Referring to FIGS. 7B, 9, and 11C, in order to fix the second interposer 640 in the manufacturing process of the array substrate, the unit dummy 70 is disposed in the space 642 in the second interposer 640, and the second interposer 640 and the unit dummy 790 may be connected by a plurality of third bridges 760. When the fourth plating layer 646a is formed on the second side surface 646 of the second interposer 640, a third bridge 760 (or a plurality of third bridges 760) becomes a mask, such that the fourth plating layer 646a is not formed at a fourth bridge connection portion 647.

When the third bridge 760 connecting the second interposer 640 and the unit dummy 790 is removed, the fourth plating layer 646a does not exist at the fourth bridge connection portion 647 where the third bridge 760 was connected of the second side surface 646 of the second interposer 640. The fourth plating layer 646a may be formed at other portions except for the fourth bridge connection portion 647 of the second side surface 646 of the second interposer 640. The fourth plating layer 646a may be electrically connected with at least one ground via 648b formed in the second interposer 640. The region corresponding to the fourth bridge connection portion 647, where the fourth plating layer 646a does not exist, may be shielded by a plurality of ground vias 648b.

As described above, the fourth plating layer 646a is formed on the second side surface 646 of the first interposer 640 and the region (e.g., the fourth bridge connection portion 647) where the fourth plating layer 646a is not formed may be shielded by the plurality of ground vias 648b. Accordingly, it is possible to remove or reduce EMI among parts disposed inside and/or outside the second interposer 640.

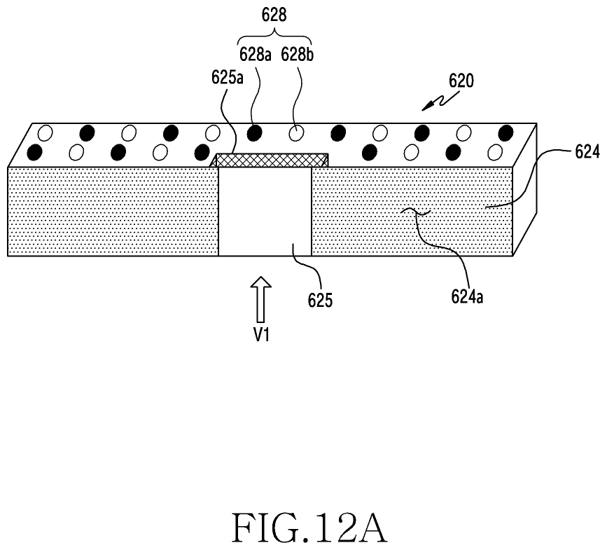

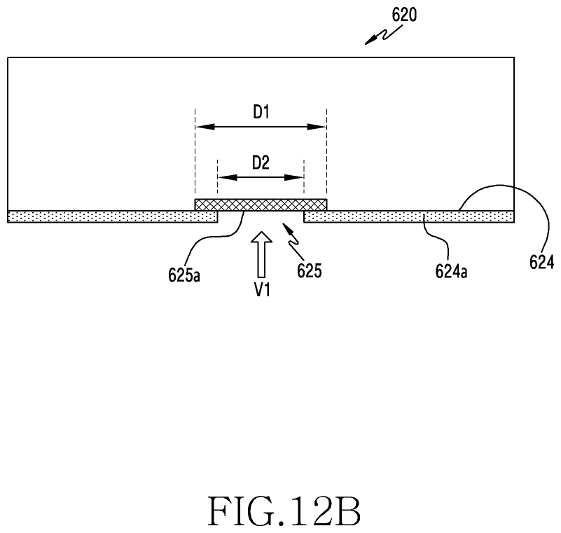

FIG. 12A illustrates a shield layer formed inside a first side surface (e.g., outer side surface) of a first interposer, according to an embodiment. FIG. 12B illustrates a shield layer formed inside a first side surface (e.g., outer side surface) of a first interposer, according to an embodiment.

Referring to FIGS. 12A and 12B, in the manufacturing process, when a first bridge connecting an array substrate and the first interposer 620 is removed, a first plating layer 624a does not exist at the first bridge connection portion 625 where the first bridge was connected of the first side surface 624 of the first interposer 620. The first plating layer 624a may be formed at other portions except for the first bridge connection portion 625 of the first side surface 624 of the first interposer 620.

In order to shield EMI, a first shield layer 625a may be formed at a portion adjacent to the first bridge connection portion 625 in the first interposer 620. The first shield layer 625a may be made of a conductive material (e.g., copper, aluminum, STS, or magnesium, or an alloy formed by combining at least two of these substances), and may be electrically connected with at least one ground via 628b. The first shield layer 625a may be formed with a height substantially the same as the first interposer 620. The width D1 of the first shield layer 625a may be the same as or larger than the width D2 of the first bridge connection portion 625. The width D1 of the first shield layer 625a is the same as or larger than the width D2 of the first bridge connection portion 625, in order to prevent generation of EMI interference due to the first bridge connection portion 625. Accordingly, it is possible to remove or reduce EMI among parts disposed inside and/or outside the first interposer 620.

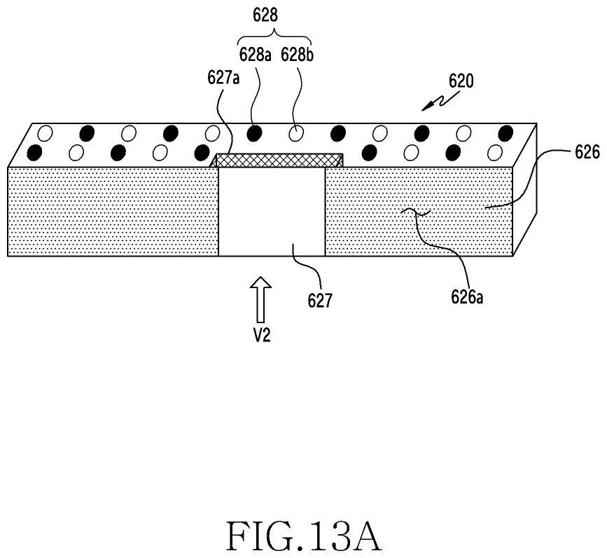

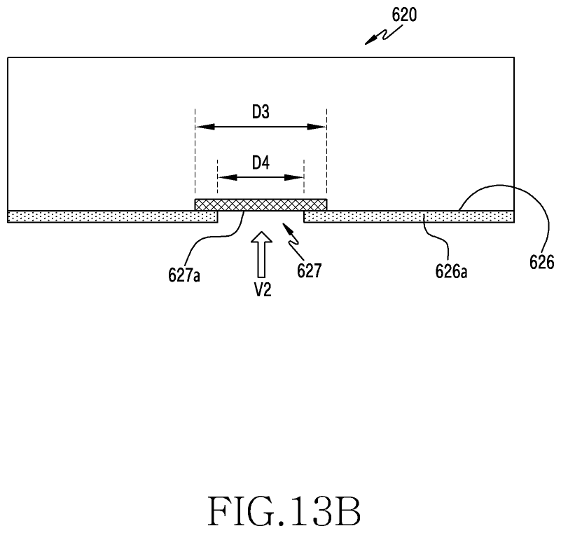

FIG. 13A illustrates a shield layer formed inside a second side surface (e.g., inner side surface) of a first interposer, according to an embodiment. FIG. 13B illustrates a shield layer formed inside a second side surface (e.g., inner side surface) of a first interposer, according to an embodiment.

Referring to FIGS. 13A and 13B, in the manufacturing process, when a second bridge connecting the first interposer 620 and a second interposer is removed, a second plating layer 626a does not exist at the second bridge connection portion 627 where the second bridge was connected of the second side surface 626 of the first interposer 620. The second plating layer 626a may be formed at other portions except for the second bridge connection portion 627 of the second side surface 626 of the second interposer 620.

In order to shield EMI, the second shield layer 627a may be formed at a portion adjacent to the second bridge connection portion 627 in the first interposer 620. The second shield layer 627a may be made of a conductive material (e.g., copper, aluminum, STS, or magnesium, or an alloy formed by combining at least two of these substances), and may be electrically connected with at least one ground via 628b. The second shield layer 627a may be formed with a height substantially the same as the first interposer 620. The width D3 of the second shield layer 627a may be the same as or larger than the width D4 of the second bridge connection portion 627. The width D3 of the second shield layer 627a is the same as or larger than the width D4 of the second bridge connection portion 627, in order to prevent generation of EMI interference due to the second bridge connection portion 627. Accordingly, it is possible to remove or reduce EMI among parts disposed inside and outside the first interposer 620.

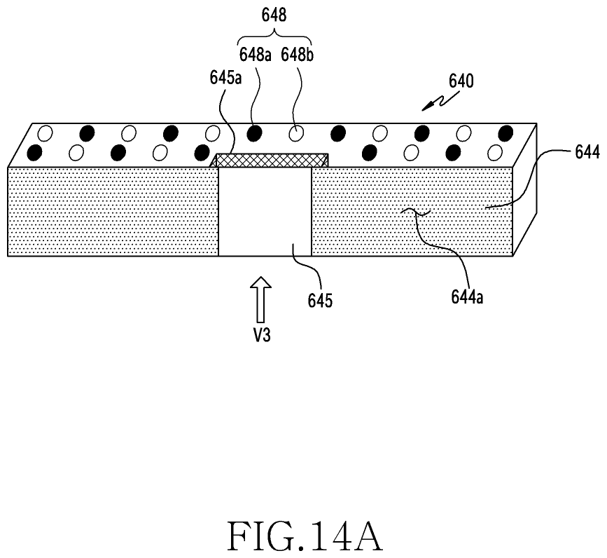

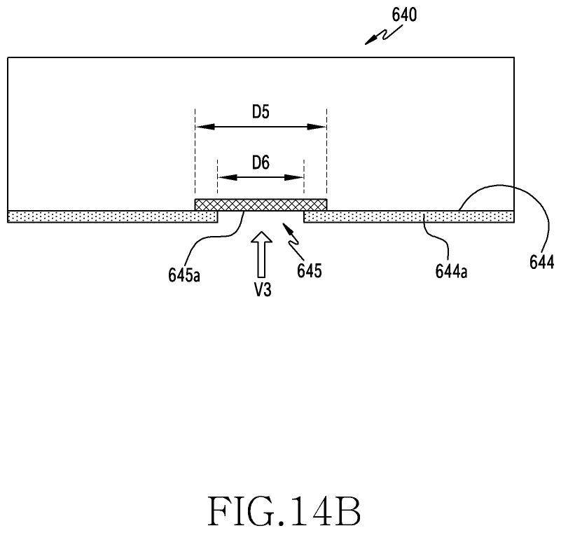

FIG. 14A illustrates a shield layer formed inside a first side surface (e.g., outer side surface) of a second interposer, according to an embodiment. FIG. 14B illustrates a shield layer formed inside a first side surface (e.g., outer side surface) of a second interposer, according to an embodiment.

Referring to FIGS. 14A and 14B, when a plurality of second bridges connecting the first interposer 620 and a second interposer is removed, a third plating layer 644a does not exist at the third bridge connection portion 645 where the second bridge was connected of the first side surface 644 of the second interposer 640. The third plating layer 644a may be formed at other portions except for the third bridge connection portion 645 of the first side surface 644 of the second interposer 640.

In order to shield EMI, the third shield layer 645a may be formed at a portion adjacent to the third bridge connection portion 645 in the second interposer 640. The third shield layer 645a may be made of a conductive material (e.g., copper, aluminum, STS, or magnesium, or an alloy formed by combining at least two of these substances), and may be electrically connected with at least one ground via 648b. The third shield layer 645a may be formed with a height substantially the same as the second interposer 640. The width D5 of the third shield layer 645a may be the same as or larger than the width D6 of the third bridge connection portion 645. The width D5 of the third shield layer 645a is the same as or larger than the width D6 of the third bridge connection portion 645, in order to prevent generation of EMI interference due to the third bridge connection portion 645. Accordingly, it is possible to remove or reduce EMI among parts disposed inside and outside the second interposer 640.

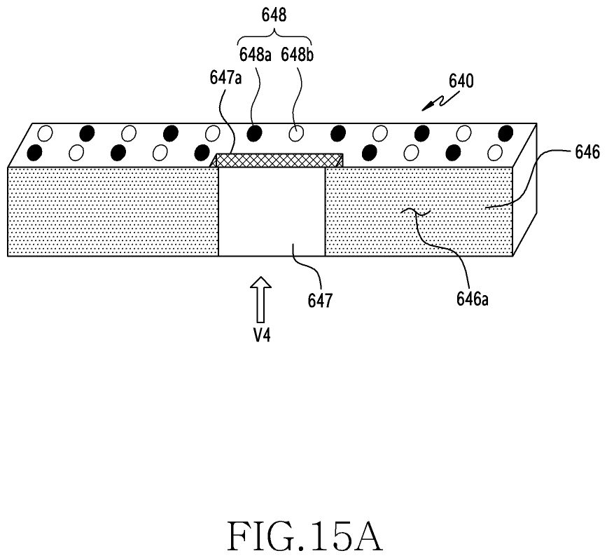

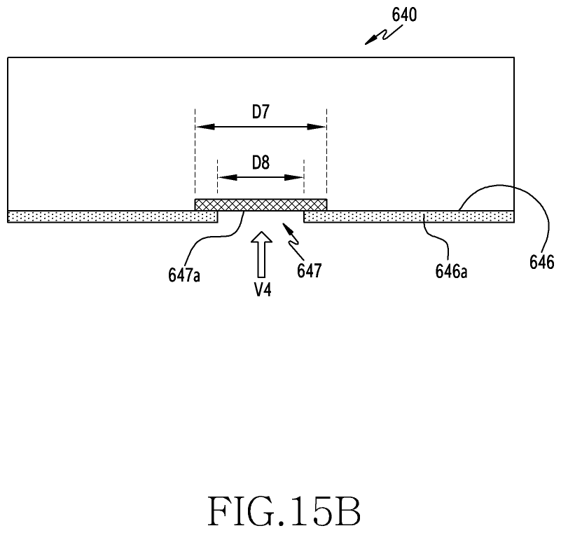

FIG. 15A illustrates a shield layer formed inside a second side surface (e.g., inner side surface) of a second interposer, according to an embodiment. FIG. 15B illustrates a shield layer formed inside a second side surface (e.g., inner side surface) of a second interposer, according to an embodiment.

Referring to FIGS. 7B, 15A, and 15D, in the manufacturing process, the second interposer 640 and the unit dummy 790 may be connected by the third bridge 760. A first side 760a of the third bridge 760 may be connected to the second side surface 646 (e.g., inner side surface) of the second interposer 640. A second side 760b of the third bridge 760 may be connected to the unit dummy 790. When the first interposer 620 and the second interposer 640 finish being manufactured, it is possible to remove the first bridge 720, the second bridge 740, and the third bridge 760 by cutting.

When the third bridge 760 (or a plurality of third bridges 760) connecting the second interposer 640 and the unit dummy 790 is removed, the fourth plating layer 646a does not exist at the fourth bridge connection portion 647 where the third bridge 760 was connected of the second side surface 646 of the second interposer 640. The fourth plating layer 646a may be formed at other portions except for the fourth bridge connection portion 647 of the second side surface 646 of the second interposer 640.

In order to shield EMI, the fourth shield layer 647a may be formed at a portion adjacent to the fourth bridge connection portion 647 in the second interposer 640. The fourth shield layer 647a may be made of a conductive material (e.g., copper, aluminum, STS, or magnesium, or an alloy formed by combining at least two of these substances), and may be electrically connected with at least one ground via 648b. The fourth shield layer 647a may be formed with a height substantially the same as the second interposer 640. The width D7 of the fourth shield layer 647a may be the same as or larger than the width D8 of the fourth bridge connection portion 647. The width D7 of the fourth shield layer 647a is the same as or larger than the width D8 of the fourth bridge connection portion 647, in order to prevent generation of EMI interference due to the fourth bridge connection portion 647. Accordingly, it is possible to remove or reduce EMI among parts disposed inside and/or outside the second interposer 640.

As described above, an interposer array according to an embodiment may include an array substrate, a first interposer that is a closed curve having a first space therein, a second interposer that is a closed curve having a second space therein, a plurality of first bridges connecting the array substrate and the first interposer and a plurality of second bridges connecting the first interposer and the second interposer.

The second interposer may be disposed in the first space of the first interposer.

The interposer array may further include a unit dummy disposed in the second space of the second interposer. The interposer array may further include a plurality of third bridges connecting the second interposer and the unit dummy.

The first interposer and the second interposer of the interposer array may be simultaneously formed through the same manufacturing process.

The first interposer and the second interposer of the interposer array may be formed to have substantially the same height.

In the interposer array, a first plating layer may be formed on an outer side surface of the first interposer, a second plating layer may be formed on an inner side surface of the first interposer, a third plating layer may be formed on an outer side surface of the second interposer, and a fourth plating layer may be formed on an inner side surface 646 of the second interposer.

In the interposer array, the plurality of first bridges and the plurality of second bridges may be removed, and the first interposer and the second interposer may be separated.

An interposer according to an embodiment, which is a first interposer that is a closed curve having the first space therein, may be disposed between a first PCB and a second PCB that are vertically stacked, and may include a first plating layer formed on a first side surface outside the first space.

A non-plating portion may be formed on the first side surface outside the first space of the first interposer.

A second plating layer may be formed on a second side surface inside the first space of the first interposer.

A non-plating portion may be formed on the second side surface inside the first space of the first interposer.

A second interposer that is a closed curve having a second space therein may be disposed between the first PCB and a third PCB that are vertically stacked, and may be formed in a size smaller than the first space of the first interposer.

A third plating layer may be formed on a first side surface outside the second space of the second interposer.

A non-plating portion may be formed on the first side surface outside the second space of the second interposer.

A fourth plating layer formed on a second side surface inside the second space of the second interposer may be included.

A non-plating portion may be formed on the second side surface inside the second space of the second interposer.

An electronic device according to an embodiment includes a first package substrate 500 and a second package substrate. The first package substrate may include a first PCB, a second PCB vertically stacked on the first PCB, and a first interposer disposed between the first PCB and the second PCB. The second package substrate may include a third PCB, a fourth PCB vertically stacked on the third PCB, and a second interposer disposed between the third PCB and the fourth PCB. The first interposer may be a closed curve having a first space therein, the second interposer may be a closed curve having a second space therein, and the second interposer may be formed in a size smaller than the first space of the first interposer.

A first plating layer may be formed on an outer side surface of the first interposer, a second plating layer may be formed on an inner side surface of the first interposer, a third plating layer may be formed on an outer side surface of the second interposer, and a fourth plating layer may be formed on an inner side surface of the second interposer.

A plurality of first plating portions may be formed on the outer side surface of the first interposer and a plurality of second non-plating portions may be formed on the inner side surface of the first interposer.

A plurality of third plating portions may be formed on the outer side surface of the second interposer and a plurality of fourth non-plating portions may be formed on the inner side surface of the second interposer.

An electronic device according to an embodiment may be one of various types of electronic devices. For example, an electronic devices may include a portable communication device (e.g., a smartphone), a computer device, a portable multimedia device, a portable medical device, a camera, a wearable device, or a home appliance. However, an electronic device is not limited to one of those described above.

The above-described embodiments of the disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements. A singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

As used herein, such terms as “1st” and “2nd,” or “first” and “second” may be used to simply distinguish a corresponding component from another, and does not limit the components in other aspect (e.g., importance or order).

If an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration.

According to various embodiments, operations performed by the module, the program, or another component may be carried out sequentially, in parallel, repeatedly, or heuristically, or one or more of the operations may be executed in a different order or omitted, or one or more other operations may be added.

According to the above-described embodiments, an interposer having a via and a component-mounting space formed therein may be disposed between a first PCB and a second PCB, and the first PCB and the second PCB may be vertically stacked. Accordingly, the area of each PCB may be reduced, and the reduced area of each PCB may in turn make it possible to secure a space for mounting a component and/or a battery inside the electronic device.

Further, an interposer array including different types of interposers may be manufactured through a single manufacturing method, thereby reducing the time and cost for manufacturing interposers.

A conductive material (e.g., copper) may be formed on the inner surface/outer surface of a first interposer and a second interposer, which are of different types, thereby removing or reducing the EMI between components disposed inside and/or outside the first interposer and the second interposer.

Different types of interposers may be simultaneously pre-soldered, thereby improving the interposer productivity.

Additionally, different types of interposers manufactured through a single manufacturing method may be mounted on a single electronic device, thereby improving the thickness dispersion of the electronic device.

While the disclosure has been particularly shown and described with reference to embodiments thereof, it will be understood by those skilled in the art that various changes in form and details may be made therein without departing from the scope of the subject matter as defined by the appended claims and their equivalents.

What is claimed is:

1. An interposer array, comprising:
an array substrate;
a first interposer configured as a closed curve having a first space therein;
a second interposer configured as a closed curve having a second space therein;
a plurality of first bridges configured to connect the array substrate and the first interposer; and
a plurality of second bridges configured to connect the first interposer and the second interposer.

2. The interposer array of claim 1, wherein the second interposer is disposed in the first space of the first interposer.

3. The interposer array of claim 1, further comprising:
a unit dummy disposed in the second space of the second interposer; and
a plurality of third bridge configured to connect the second interposer and the unit dummy.

4. The interposer array of claim 1, wherein the first interposer and the second interposer are simultaneously formed in a manufacturing process.

5. The interposer array of claim 1, wherein the first interposer and the second interposer are formed to have substantially the same height.

6. The interposer array of claim 1, further comprising:
a first plating layer formed on an outer side surface of the first interposer,
a second plating layer formed on an inner side surface of the first interposer,
a third plating layer formed on an outer side surface of the second interposer, and
a fourth plating layer formed on an inner side surface of the second interposer.

7. The interposer array of claim 6, wherein the plurality of first bridges and the plurality of second bridge are removed to separate the first interposer and the second interposer.

8. An interposer comprising:
a first interposer configured as a first closed curve having a first space therein, wherein the first interposer is disposed between a first printed circuit board (PCB) and a second PCB that are vertically stacked, and
a first plating layer formed on a first side surface outside the first space.

9. The interposer of claim 8, further comprising a non-plating portion formed on the first side surface outside the first space.

10. The interposer of claim 8, further comprising a second plating layer formed on a second side surface inside the first space.

11. The interposer of claim 10, further comprising a non-plating portion formed on the second side surface inside the first space.

12. The interposer of claim 8, further comprising a second interposer configured as a closed curve having a second space therein, wherein the second interposer is disposed between the first PCB and a third PCB that are vertically stacked, and is smaller in size than the first space of the first interposer.

13. The interposer of claim 12, further comprising a third plating layer formed on a first side surface outside the second space.

14. The interposer of claim 13, further comprising a first non-plating portion formed on the first side surface outside the second space.

15. The interposer of claim 13, further comprising a fourth plating layer formed on a second side surface inside the second space.

16. The interposer of claim 15, further comprising a non-plating portion formed on the second side surface inside the second space.

17. An electronic device, comprising:
a first package substrate including:
a first printed circuit board (PCB),
a second PCB vertically stacked on the first PCB, and
a first interposer disposed between the first PCB and the second PCB; and
a second package substrate including:
a third PCB,
a fourth PCB vertically stacked on the third PCB, and
a second interposer disposed between the third PCB and the fourth PCB,
wherein the first interposer is configured as a closed curve having a first space therein,
wherein the second interposer is configured as a closed curve having a second space therein, and
wherein the second interposer is smaller in size than the first space of the first interposer.

18. The electronic device of claim 17, further comprising:
a first plating layer formed on an outer side surface of the first interposer,
a second plating layer formed on an inner side surface of the first interposer,
a third plating layer formed on an outer side surface of the second interposer, and
a fourth plating layer formed on an inner side surface of the second interposer.

19. The electronic device of claim 18, further comprising:
a plurality of first non-plating portions formed on the outer side surface of the first interposer; and
a plurality of second non-plating portions formed on the inner side surface of the first interposer.

20. The electronic device of claim 18, further comprising:
a plurality of third non-plating portions formed on the outer side surface of the second interposer; and
a plurality of fourth non-plating portions formed on the inner side surface of the second interposer.
